(19) United States
(12) Patent Application Publication
(10) Pub. No.: US 2005/0247953 A1
(43) Pub. Date: Nov. 10, 2005

(54) White light-emitting device

(76) Inventors: Yi-Shan Lin, Tsao-Tun Jen (TW); Ru-Shi Liu, Chu-Tung Jen (TW); Hung-Yuan Su, Chung Ho (TW)

Correspondence Address: BIRCH STEWART KOLASCH & BIRCH, PO BOX 747, FALLS CHURCH, VA, 22040-0747, US

(21) Appl. No.: 10/944,770

(22) Filed: Sep. 21, 2004

(30) Foreign Application Priority Data
May 7, 2004 (CN) 93112966

(51) Int. Cl. H01L 29/24

(52) U.S. Cl. 257/103

(57) ABSTRACT

A white light-emitting device has a semiconductor light-emitting chip, a blue-green phosphor and a red phosphor for emitting blue-green light and red light, respectively. The blue-green phosphor and the red phosphor absorb light emitted from the semiconductor light-emitting chip to excite blue-green light and red light that are mixed into white light with improved illumination efficiency, and a high color-rendering property. The white light-emitting device is cheaply and simply manufactured.

### BACKGROUND OF THE INVENTION

1. Field of the Invention

The invention relates to white light-emitting device, and more particularly to white light-emitting device including more than one phosphor to absorb light emitted from a semiconductor light-emitting chip to excite lights that are then mixed into white light.

2. Description of the Related Art

White light is a light mixed from a plurality of lights of different colors. Visible white light is generated by mixing at least two lights of different wavelengths. For example, when red, blue and green lights, or blue and yellow lights, simulate the eyes at the same time, the eyes recognize the incident light as white light. A light-emitting diode (LED) light source is made based on this theory. Four processes are commonly used to generate white light for an LED device in the art. The first process uses InGaAlP, GaN and GaN to make LED devices that respectively control currents passing through LED devices to generate the red, green and blue light. Since these three LED devices are placed in one lamp, the lens of the lamp mixes the lights emitted from the LED devices to generate white light. The second process uses GaN and GaP to make two LED devices for controlling an electrical current passing through the LED devices to emit blue and yellow-green light, respectively. The blue and yellow-green lights are mixed to generate white light. These two methods provide 20 lm/W of illumination. However, if one of the LED devices responsible for providing a specific color of light malfunctions, then white light will typically not be obtained. Furthermore, since positive biases applied on these LED devices are different, several control circuits to control the biases are required, causing an increase in production cost. The third process was developed by Nichia Chemical Company, Japan, in 1996, which uses InGaN blue diode and yellow yttrium aluminum garnet powder to provide white light. The illumination of this process currently reaches 15 lm/W, which is less than that of the above two processes; however, only one LED device is needed. This process has been successfully commercialized due to the mature technology of preparing the phosphors powder. The second process and the third processes implement the complementary color principle to generate white light. The continuity of spectrum wavelength distribution is not as good as that of sunlight. Therefore, white light obtained by mixing lights appears non-uniform in color in the visible light range (490 nm-700 nm), resulting in low color saturation. Although human eyes can neglect the phenomenon and just see white light, high-precision optical detecting equipment, such as cameras or other picture shooting devices, has a color rendering property. That is, some errors may be generated when colors of an object return to their original conditions. Therefore, white light generated by such a process in only suitable for simple illumination applications. A fourth process was developed by Sumitomo Electric Industries, Ltd, Japan in 1999. In the fourth process, a CdZnSe film is formed on a ZeSe single-crystal substrate to emit a blue light. The blue light also irradiates the substrate to emit a yellow light. The blue light and the yellow light are complementary colors and generate white light. In this process, one LED device is used and the operational voltage is only 2.7V, rather smaller than 3.5V for the LED device formed on GaN. No phosphor is needed for obtaining white light. However, a main disadvantage thereof is that the illumination is only 8 lm/W, and the service life is only 8000 hours, which limits applications thereof.

### SUMMARY OF THE INVENTION

It is therefore an object of the invention to provide a white light-emitting device, in which a semiconductor light-emitting chip emits a light that is absorbed by the (Ba₁₋ₓMₓ)Al₂O₄ phosphor (M is Eu, Bi, Mn, Ce, Tb, Gd, La, Mg and Sr, or 1>x>0) to emit a blue-green light, and is also absorbed by the (Y₂₋ₓR_{X})O₃ phosphor to emit a red light (R is at least one of Eu, Bi or Gd, and 0<x≦0.5). The blue-green and red lights are mixed to generate white light. In variants, the (Y₂₋ₓRₓ)O₃ phosphor is replaced by (Y₂₋ₓR_{X})O₂S phosphor. The (Y₂₋ₓRₓ)O₂S also emits red light after absorbing the light emitted from the semiconductor light-emitting chip.

In order to achieve the above and other objectives, a white light-emitting device of the invention includes a semiconductor light-emitting chip, at least one (Ba₁₋ₓMₓ)Al₂O₄phosphor, and at least one (Y₂₋ₓRₓ)O₃ phosphor. The semiconductor light-emitting chip is configured to emit light. The (Ba₁₋ₓMₓ)Al₂O₄ phosphor absorbs the light emitted from the semiconductor light-emitting chip, and excites a first color light, in which M is at least one of Eu, Bi, Mn, Ce, Tb, Gd, La, Mg and Sr, or 1>x>0. The (Y₂₋ₓRₓ)O₃ phosphor absorbs light emitted from the semiconductor light-emitting chip to excite a second color light, in which R is at least one of Eu, Bi and Gd, and 0<x≦0.5. The first and second color lights are mixed to generate white light.

According to another embodiment of the invention, white light-emitting device includes a semiconductor light-emitting chip, at least one (Ba₁₋ₓMₓ)Al₂O₄ phosphor, and at least one (Y₂₋ₓRₓ)O₂S phosphor. The semiconductor light-emitting chip is configured to emit light. The (Ba₁₋ₓMₓ)Al₂O₄ phosphor to absorb the light emitted from the semiconductor light-emitting chip to excite a first color light, in which M is at least one of Eu, Bi, Mn, Ce, Tb, Gd, La, Mg and Sr, and 1>x>0. The (Y₂₋ₓRₓ)O₂S phosphor to absorb the light emitted from the semiconductor light-emitting chip to excite a second color light, in which R is at least one of Eu, Bi and Gd, and 0<x≦0.5. The first and second color lights are mixed to generate white light.

Mixing only two phosphors allows the generation of white light with high color rendering property and illumination. The process is simple and cheap. Therefore, the invention has high industrial utility.

To provide a further understanding of the invention, the following detailed description illustrates embodiments and examples of the invention, this detailed description being provided only for illustration of the invention.

### BRIEF DESCRIPTION OF THE DRAWINGS

The drawings included herein provide a further understanding of the invention. A brief introduction of the drawings is as follows:

FIG. 1 is a schematic view of a white light-emitting device according to one embodiment of the invention;

FIG. 2 is an excitation and emission spectrums of (Ba₁₋ₓMₓ)Al₂O₄ (1>x>0, and M is at least one selected from Eu, Bi, Mn, Ce, Tb, Gd, La, Mg, Sr) according to one embodiment of the invention;

FIG. 3 is an excitation and emission spectrums of (Y_{1.9}Eu_{0.1})O₃ according to one embodiment of the invention;

FIG. 4 is a spectrum of white light obtained by mixing two phosphors; and

FIG. 5 is a colorimetric coordinate converted from the spectrum of FIG. 4.

### DETAILED DESCRIPTION OF PREFERRED EMBODIMENTS

Wherever possible in the following description, like reference numerals will refer to like elements and parts unless otherwise illustrated.

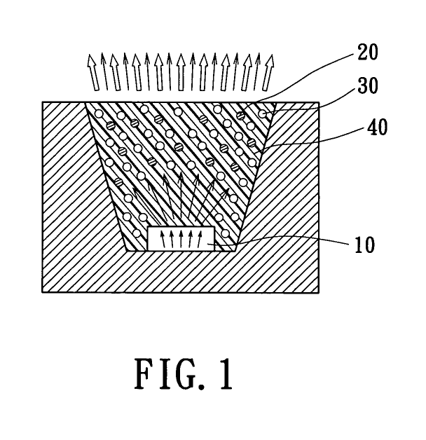

As shown in FIG. 1, a white light-emitting device of the invention-includes a semiconductor light-emitting chip 10, at least one (Ba₁₋ₓMₓ)Al₂O₄ phosphor 20 (where M is at least one of Eu, Bi, Mn, Ce, Tb, Gd, La, Mg and Sr, or 1>x>0), and at least one (Y₂₋ₓRₓ)O₃ phosphor 30 (where R is at least one of Eu, Bi and Gd, and 0<x≦0.5). The (Ba₁₋ₓMₓ)Al₂O₄ phosphor 20 and the (Y₂₋ₓRₓ)O₃ phosphor 30 absorb the light emitted from the semiconductor light-emitting chip 10 to emit blue-green and red light, which are then mixed to generate white light.

The light emitted from the semiconductor light-emitting chip 10 is an ultraviolet light with wavelength peak at 350-480 nm. The ultraviolet light thus generated is absorbed by the (Ba₁₋ₓMₓ)Al₂O₄ phosphor 20 and the (Y₂₋ₓRₓ)O₃ phosphor 30 to excite blue-green light having a wavelength of 450 nm to 575 nm and red light having a wavelength of 585 nm to 640 nm, respectively. The blue-green light and the red light are mixed to generate white light. The white light-emitting device can be complemented by mixing the (Ba₁₋ₓMₓ)Al₂O₄ phosphor 20 and the (Y₂₋ₓRₓ)O₃ phosphor 30 with an encapsulant 40, as shown in FIG. 1. An electrical current passing through the semiconductor light-emitting chip 10 stimulates the chip 10 to emit ultraviolet light. The phosphors 20, 30 absorb the ultraviolet light to excite the blue-green light and the red light that can be mixed to generate white light.

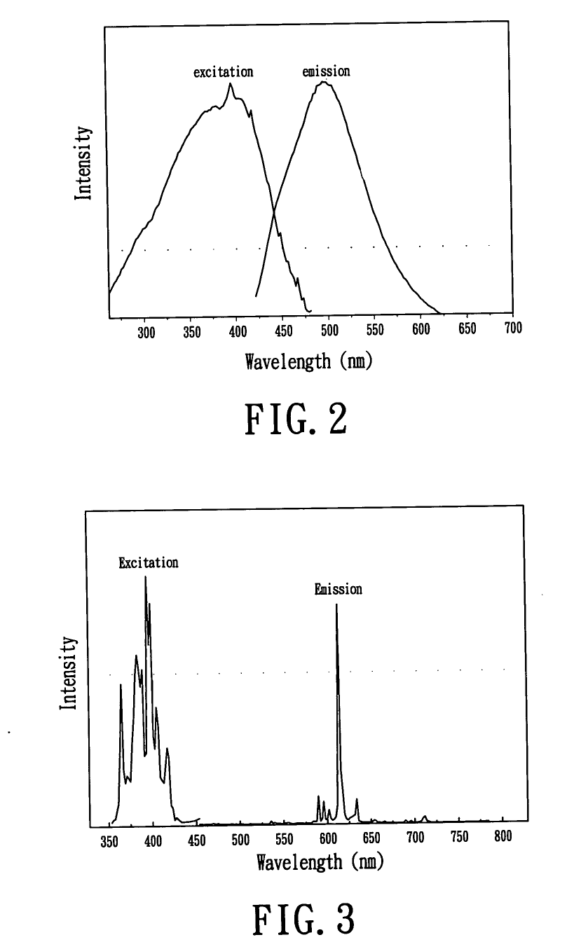

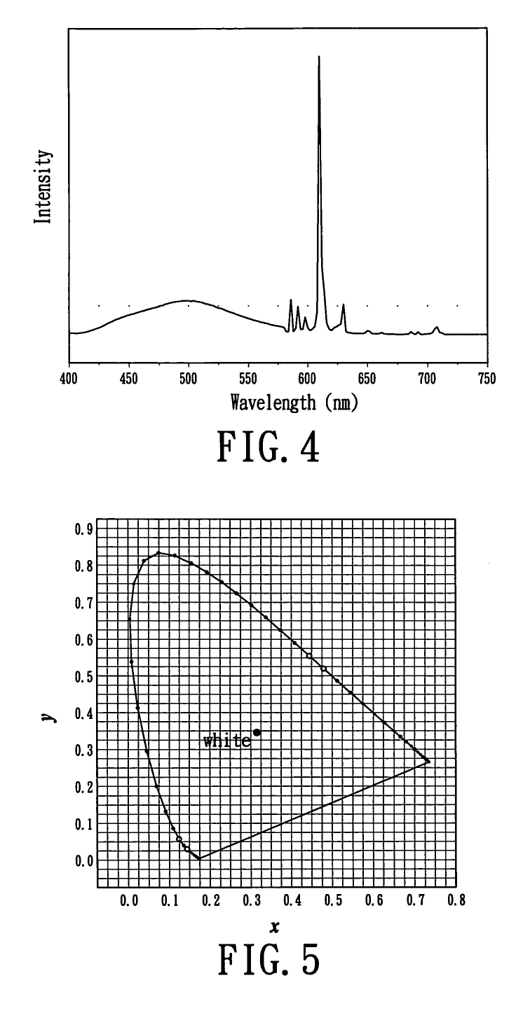

FIG. 2 is excitation and emission spectra of (Ba₁₋ₓMₓ)Al₂O₄ according to one embodiment of the invention. FIG. 3 is excitation and emission spectra of (Y₂₋ₓRₓ)O₃ according to one embodiment of the invention. FIG. 4 is a spectrum of white light obtained by mixing two phosphors. FIG. 5 is a colorimetric coordinate converted from the spectrum of FIG. 4

When the (Ba₁₋ₓMₓ)Al₂O₄ phosphor 20 and the (Y₂₋ₓRₓ)O₃ phosphor 30 are in the form of powder, the following steps are performed:

Step 1: preparing (Y_{1.9}Eu_{0.1})O₃ phosphor from Y₂O₃ and Eu-containing compounds. The method used to prepare the (Y_{1.9}Eu_{0.1})O₃ phosphor includes solid reaction, chemical synthesis, citrate gel process, co-precipitation and the like.

Step 2: preparing (Ba₁₋ₓMₓ)Al₂O₄ phosphor such as (Ba_{0.9}Eu_{0.1})Al₂O₄, where 1>x>0′ M is at least one of Eu, Bi, Mn, Ce, Tb, Gd, La, Mg or Sr. The method used to prepare the (Ba₁₋ₓMₓ)Al₂O₄ phosphor includes solid reaction and co-precipitation.

Step 3: detecting the excitation and emission spectrums for (Y_{1.9}Eu_{0.1})O₃ phosphor by using an excimer spectrometer, as shown in FIG. 2. It is found that the Y₂O₃: Eu phosphor is excited by the ultraviolet light (350 nm-480 nm) to emit the red light having a wavelength of 610 nm.

Step 4: detecting the excitation and emission spectrums for (Ba₁₋ₓMₓ)Al₂O₄ phosphor by using an excimer spectrometer, as shown in FIG. 3. It is found that (Ba₁₋ₓMₓ)Al₂O₄ phosphor is excited by the ultraviolet light having a wavelength of 350 nm to 480 nm to emit a wide waveband blue-green light in the wavelength range from blue light to green light (about 500 nm).

Step 5: the two phosphors are mixed in an appropriate ratio (such as 1:1) to obtain white light that exhibits the spectrum as shown in FIG. 4. The spectrum is converted into colorimetric coordinate as shown in FIG. 5.

Step 6: the two phosphors are mixed in an appropriate ratio (such as 1:1) to emit the ultraviolet light of appropriate wavelength (for example, 396 nm) as an excitation light source. The phosphors are properly packaged to obtain a white light-emitting device that provides good illumination when voltage is applied thereto.

The(Y₂₋ₓRₓ)O₃ phosphor 30 can be replaced by (Y₂₋ₓRₓ)O₂S phosphor to absorb the light emitted from and excite the light as (Y₂₋ₓRₓ)O₃ phosphor emits. The (Ba₁₋ₓMₓ)Al₂O₄ phosphor such as (Ba_{0.9}Eu_{0.1})Al₂O₄, and the (Y₂₋ₓRₓ)O₂S phosphor such as (Y_{1.9}Eu_{0.1})O₂S mixed in a ratio of 1:1 can absorb the light emitted from the semiconductor light-emitting chip 10 to excite the blue-green and red light and thus obtain white light.

The invention is not limited to the above embodiment. Any wide-waveband phosphor that contains optical active centers in its main cell or is used in combination with sensitivity increasing agents to emit broad light range from red light to green light (480 nm to 650 nm) or to emit blue to green light (430 nm to 500 nm) can be also used in the invention. The composition containing two phosphors exhibits advantageous illumination properties such as high color uniformity, high brightness.

As described above, the (Ba₁₋ₓMₓ)Al₂O₄ (M is at least one of Eu, Bi, Mn, Ce, Tb, Gd, La, Mg and Sr, or 1>x>0) phosphor absorbs the light emitted from the semiconductor light-emitting chip to emit the blue-green light. The (Y₂₋ₓRₓ)O₃ (R is at least one selected from Eu, Bi or Gd, and 0<x≦0.5) phosphor also absorbs the light emitted from the semiconductor light-emitting chip to emit the red light. The (Y₂₋ₓRₓ)O₃ phosphor can be replaced by a (Y₂₋ₓRₓ)O₂S phosphor. Mixing only two phosphors allows the generation of white light with a high color rendering property and illumination. The process is simple and cheap. Therefore, the invention has high industrial utility.

It should be apparent to those skilled in the art that the above description is only illustrative of specific embodiments and examples of the invention, and should not be construed in a limiting way. Therefore, the invention should cover various modifications and variations made to the herein-described structure and operations of the invention, provided they fall within the scope of the invention as defined in the following appended claims.

1. A white light-emitting device, comprising:
a semiconductor light-emitting chip, configured to emit light;
at least one (Ba₁₋ₓMₓ)Al₂O₄ phosphor to absorb light emitted from the semiconductor light-emitting chip to excite a first color light, wherein M is at least one of Eu, Bi, Mn, Ce, Tb, Gd, La, Mg and Sr, or 1>x>0; and
at least one (Y₂₋ₓRₓ)O₃ phosphor to absorb the light emitted from the semiconductor light-emitting chip to excite a second color light, wherein R is at least one of Eu, Bi and Gd, and 0<x≦0.5;
wherein the first and second color light are mixed to generate white light.

2. The device of claim 1, wherein the light emitted from the semiconductor light-emitting device is an ultraviolet light.

3. The device of claim 2, wherein a wavelength peak of the ultraviolet light is in a range of about 350 nm-480 nm.

4. The device of claim 1, wherein the first color light is a blue-green light having a wavelength ranging from about 450 to 575 nm.

5. The device of claim 1, wherein the second color light is a red light having a wavelength ranging from about 585 nm to 640 nm.

6. The device of claim 1, wherein the at least one (Ba1-xMₓ)Al₂O₄ phosphor and the at least one (Y₂₋ₓRₓ)O₃ phosphor are prepared by solid reaction or chemical synthesis.

7. The device of claim 1, wherein the at least one (Ba₁₋ₓMₓ)Al₂O₄ phosphor and the at least one (Y₂₋ₓRₓ)O₃ phosphor are prepared by co-precipitation or a citrate gel process.

8. The device of claim 1, further comprising an encapsulant, wherein the at least one (Ba₁₋ₓMₓ)Al₂O₄ phosphor and the at least one (Y₂₋ₓRₓ)O₃ phosphor in powder form are mixed with the encapsulant, and the encapsulant is used to package the semiconductor light-emitting chip.

9. The device of claim 1, wherein the (Ba₁₋ₓMₓ)Al₂O₄ phosphor is a (Ba_{0.9}Eu_{0.1})Al₂O₄ phosphor, and the (Y₂₋ₓRₓ)O₃ phosphor is a (Y_{1.9}Eu_{0.1})O₃ phosphor.

10. A white light-emitting device, comprising:
a semiconductor light-emitting chip, configured to emit light;
at least one (Ba₁₋ₓMₓ)Al₂O₄ phosphor to absorb the light emitted from the semiconductor light-emitting chip to excite a first color light, wherein M is at least one of Eu, Bi, Mn, Ce, Tb, Gd, La, Mg and Sr, or 1>x>0; and
at least one (Y₂₋ₓRₓ)O₃S phosphor to absorb the light emitted from the semiconductor light-emitting chip to excite a second color light, wherein R is at least one of Eu, Bi and Gd, and 0<x≦0.5;
wherein the first and second color light are mixed to generate white light.

11. The device of claim 10, wherein the light emitted from the semiconductor light-emitting device is an ultraviolet light.

12. The device of claim 11, wherein a wavelength peak of the ultraviolet light is in a range of about 350 nm-480 nm.

13. The device of claim 10, wherein the first color light is a blue-green light having a wavelength ranging from about 450 to 575 nm.

14. The device of claim 10, wherein the second color light is a red light having a wavelength ranging from about 585 nm to 640 nm.

15. The device of claim 10, wherein the at least one (Ba₁₋ₓMₓ)Al₂O₄ phosphor and the at least one (Y₂₋ₓRₓ)O₂S phosphor are prepared by solid reaction or chemical synthesis.

16. The device of claim 10, wherein the at least one (Ba₁₋ₓMₓ)Al₂O₄ phosphor and the at least one (Y₂₋ₓRₓ)O₂S phosphor are prepared by co-precipitation or a citrate gel process.

17. The device of claim 10, further comprising an encapsulant, wherein the at least one (Ba₁₋ₓMₓ)Al₂O₄ phosphor and the at least one (Y₂₋ₓRₓ)O₂S phosphor in powder form are mixed with the encapsulant, and the encapsulant is used to package the semiconductor light-emitting chip.

18. The device of claim 10, wherein the (Ba₁₋ₓMₓ)Al₂O₄ phosphor is a (Ba_{0.9}Eu_{0.1})Al₂O₄ phosphor, and the (Y₂₋ₓRₓ)O₂S phosphor is a (Y_{1.9}Eu_{0.1})O₂S phosphor.
